(19) United States
(12) Patent Application Publication
(10) Pub. No.: US 2025/0175022 A1
(43) Pub. Date: May 29, 2025

(54) CHARGER

(71) Applicant: Panasonic Automotive Systems Co., Ltd., Kanagawa (JP)

(72) Inventors: Masashi INOSE, Aichi Ken (JP); Naomasa SUZUKI, Kanagawa Ken (JP); Yoshihiro NAGANO, Kanagawa Ken (JP)

(73) Assignee: Panasonic Automotive Systems Co., Ltd., Kanagawa (JP)

(21) Appl. No.: 19/038,211

(22) Filed: Jan. 27, 2025

Related U.S. Application Data
(63) Continuation of application No. PCT/JP2023/041361, filed on Nov. 16, 2023.

(30) Foreign Application Priority Data
Nov. 21, 2022 (JP) 2022-185767

(51) Int. Cl. H02J 7/00; H02J 50/10; H05K 7/20

(52) U.S. Cl. CPC H02J 7/0044; H02J 50/10; H05K 7/20909

(57) ABSTRACT

A charger according to the present disclosure includes a housing, a protrusion part, and a fan. A longitudinal direction of the housing is a first direction. The housing includes a placement surface, a bottom surface, and an end surface. The placement surface enables placement of an object to be charged. The bottom surface is on an opposite side of the placement surface. The end surface is provided with an air intake port. The protrusion part is connected to one end of the housing in the first direction. The protrusion part extends in a second direction from one end. The second direction intersects the first direction. The protrusion part includes a side surface. The side surface faces the placement surface. The side surface is provided with an exhaust port. The fan is disposed in a flow path extending from the air intake port to the exhaust port.

### CROSS-REFERENCE TO RELATED APPLICATIONS

This application is a continuation of International Application No. PCT/JP2023/041361, filed on Nov. 16, 2023, which claims the benefit of priority of the prior Japanese Patent Application No. 2022-185767, filed on Nov. 21, 2022, the entire contents of which are incorporated herein by reference.

### FIELD

The present disclosure relates to a charger.

### BACKGROUND

A charger capable of wireless charging is configured to transmit power to an object to be charged, in the forms of electromagnetic energy and the like, when the object is placed on a placement surface, implementing wireless charging (see, for example, a patent literature JP 2021-40452 A).

In the charger, heat is generated during charging, and efficiency of wireless charging may be limited. For efficient wireless charging, it is desirable to efficiently perform cooling.

### SUMMARY

A charger according to the present disclosure includes a housing, a protrusion part, and a fan. A longitudinal direction of the housing is a first direction. The housing includes a placement surface, a bottom surface, and an end surface. The placement surface enables placement of an object to be charged. The bottom surface is on an opposite side of the placement surface. The end surface is provided with an air intake port. The protrusion part is connected to one end of the housing in the first direction. The protrusion part extends in a second direction from one end. The second direction intersects the first direction. The protrusion part includes a side surface. The side surface faces the placement surface. The side surface is provided with an exhaust port. The fan is disposed in a flow path extending from the air intake port to the exhaust port.

### BRIEF DESCRIPTION OF DRAWINGS

FIG. 1 is a perspective view illustrating an appearance configuration of a charger according to an embodiment;

FIG. 2 is a cross-sectional view illustrating a configuration of the charger according to an embodiment;

FIG. 3 is a cross-sectional view illustrating a cooling operation of the charger according to an embodiment;

FIG. 4 is an exploded perspective view illustrating a configuration of the charger according to an embodiment;

FIG. 5 is a perspective view illustrating a configuration of a housing and a protrusion part according to an embodiment;

FIG. 6 is a perspective view illustrating a configuration of the housing and the protrusion part according to an embodiment;

FIG. 7 is a perspective view illustrating an appearance configuration of a charger according to a first modification of the embodiment;

FIG. 8 is a cross-sectional view illustrating a configuration of the charger according to the first modification of the embodiment;

FIG. 9 is a cross-sectional view illustrating a cooling operation of the charger according to the first modification of the embodiment;

FIG. 10 is an exploded perspective view illustrating a configuration of the charger according to the first modification of the embodiment;

FIG. 11 is a perspective view illustrating a configuration of a housing and a protrusion part according to the first modification of the embodiment;

FIG. 12 is a perspective view illustrating a configuration of the housing and the protrusion part according to the first modification of the embodiment;

FIG. 13 is a cross-sectional view illustrating a configuration of a charger according to a second modification of the embodiment; and

FIG. 14 is a cross-sectional view illustrating a cooling operation of the charger according to the second modification of the embodiment.

### DETAILED DESCRIPTION

Hereinafter, embodiments of a charger according to the present disclosure will be described with reference to the drawings.

### EMBODIMENTS

A charger according to an embodiment transmits power to an object to be charged in the form of electromagnetic energy or the like when the object to be charged is placed on a placement surface, and wireless charging can be implemented. The charger is refined to efficiently cool the heat generated upon charging.

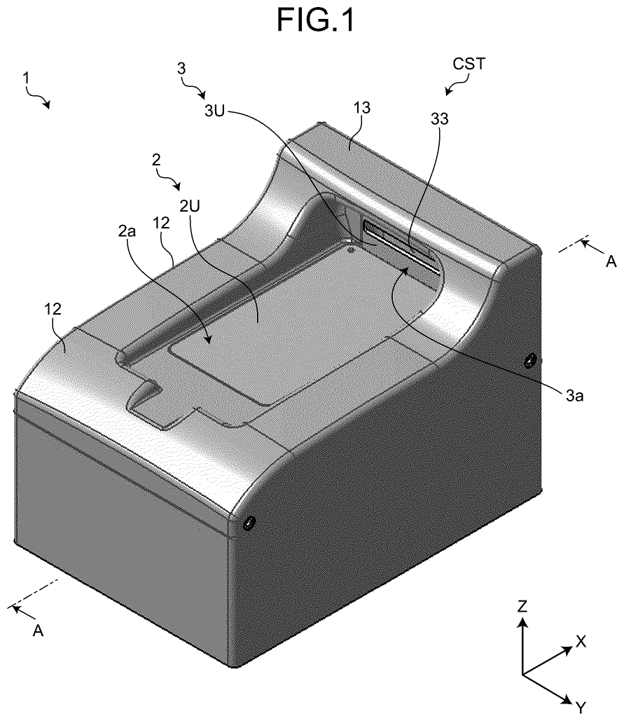

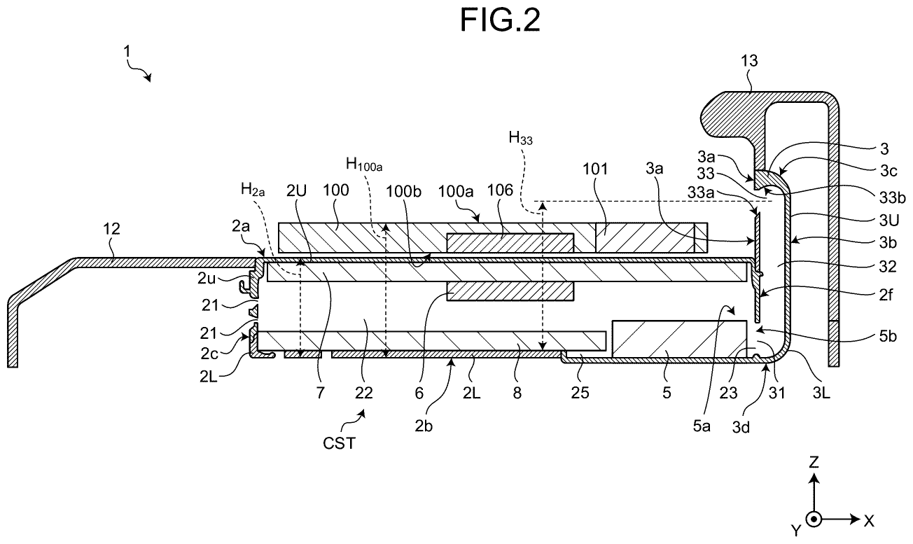

A charger 1 can be configured as illustrated in FIGS. 1 and 2. FIG. 1 is a perspective view illustrating an appearance configuration of the charger 1 according to an embodiment. FIG. 2 is a cross-sectional view of a configuration of the charger 1, illustrating a cross-section of FIG. 1 taken along line A-A.

The charger 1 has a wireless charging function and includes a placement surface 2a enabling placement of an object 100 to be charged compatible with the wireless charging function. FIG. 2 illustrates a state in which the object 100 to be charged is placed on the placement surface 2a. The charger 1 includes a housing 2 and a coil 6. In the charger 1, the coil 6 is disposed in the vicinity of the placement surface 2a in the housing 2. The object 100 to be charged includes a front surface 100a and a back surface 100b. The object 100 to be charged includes a display structure (not illustrated) in the vicinity of the front surface 100a, and includes a coil 106 in the vicinity of the back surface 100b. The charger 1 may have a wireless charging function using a moving coil type, and the coil 6 may be configured to be movable in the housing 2 in the X and Y directions. As illustrated in FIG. 2, it is considered that the charger 1 moves the coil 6 in the X and Y directions to match an XY position of the coil 6 and an XY position of the coil 106 to enable efficient wireless charging.

Wireless charging has poor charging efficiency as compared with wired charging, and tends to generate heat. Improvement of wireless charging efficiency is also studied in, for example, the Qi standard developed by the Wireless Power Consortium (WPC).

In the charger 1, the temperature of the object 100 to be charged rises during wireless charging, and the efficiency of the wireless charging may be limited. For example, according to the Qi standard, one-way communication from the object 100 to be charged to the charger 1 is performed between the charger (a power transmission side) 1 and the object 100 to be charged (a power reception side). In a case where the object 100 to be charged has a temperature protection function for electronic components such as a battery 101, a request for reducing charging power may be transmitted from the object 100 to be charged to the charger 1, in order to suppress temperature rise, when the temperature of the object 100 to be charged rises to a predetermined temperature or higher. For efficient wireless charging, it is desirable to efficiently perform cooling of the object 100 to be charged.

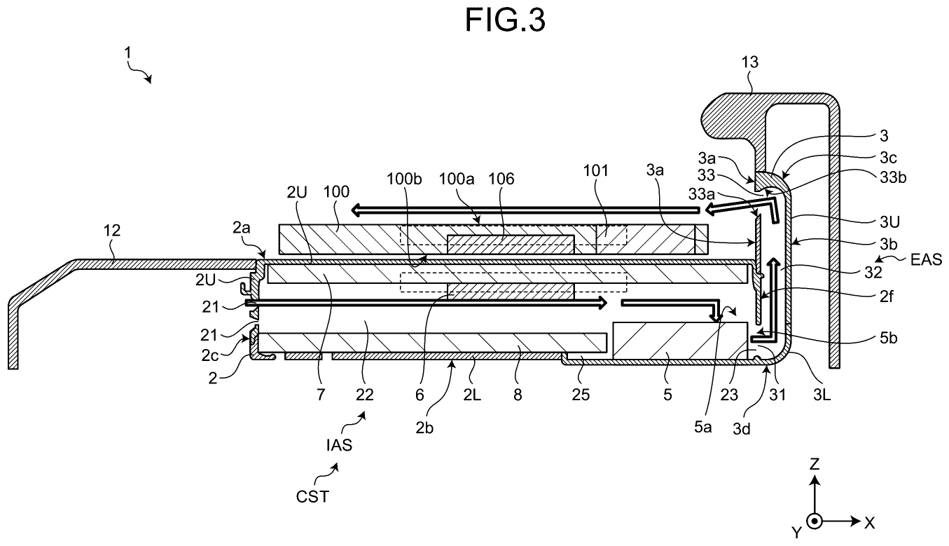

As a result of studying, it was found that an induced current flows in each of the coil 6 and the coil 106 during wireless charging, and heat can be generated in the vicinity of each of the coil 6 and the coil 106 indicated by a dotted line in FIG. 3. It is considered that the object 100 to be charged is heated due to heat conduction from a heat source (e.g., a component or the like in the vicinity of the coil 6) in the charger 1, and is also heated due to a heat source (e.g., a component or the like in the vicinity of the coil 106) in the object 100 to be charged itself.

Therefore, the charger 1 is provided with a cooling system CST configured to cool, in parallel, a region facing an internal space 22 in the charger 1 and a region in the vicinity of the front surface 100a of the object 100 to be charged.

The charger 1 includes the housing 2, a protrusion part 3, a fan 5, and the coil 6. Hereinafter, a longitudinal direction of the housing 2 is defined as the X direction, a transverse direction of the housing 2 is defined as the Y direction, and a direction perpendicular to the X direction and the Y direction is defined as a Z direction.

In the charger 1, the protrusion part 3 is connected to an end of the housing 2 on a +X side. The placement surface 2a of the housing 2 on a +Z side enables placement of the object 100 to be charged. The protrusion part 3 protrudes to the +Z side from a Z position of the placement surface 2a. Regions of end surfaces 2c to 2e of the housing 2 on the +X side are provided with air intake ports 21, and a side surface 3a of the protrusion part 3 facing the placement surface 2a is provided with an exhaust port 33. The fan 5 is disposed in a flow path extending from each of the air intake ports 21 to the exhaust port 33. The fan 5 may be disposed in a region in the housing 2 on the +X side, in the vicinity of a bottom surface 2b on an −Z side. The fan 5 is a centrifugal fan, and is provided with an air intake port 5a on the +Z side, and an exhaust port 5b on the outside in the X and Y directions (+X side in FIG. 2).

As illustrated in FIG. 3, in the internal space 22 of the housing 2, the air intake port 21 communicates with the air intake port 5a of the fan 5, and the internal space 22 forms an upstream part of the flow path extending from the air intake port 21 to the exhaust port 33. The upstream part of the flow path can be regarded as an intake air path IAS extending from the air intake port 21 to the air intake port 5a of the fan 5. FIG. 3 is a cross-sectional view illustrating a cooling operation of the charger 1.

In an internal space 32 of the protrusion part 3, the exhaust port 5b of the fan 5 communicates with the exhaust port 33, and the internal space 32 forms a downstream part of the flow path extending from the air intake port 21 to the exhaust port 33. The downstream part of the flow path can be regarded as an exhaust air path EAS extending from the exhaust port 5b of the fan 5 to the exhaust port 33.

A Z position of the exhaust port 33 is on the +Z side from the Z position of the placement surface 2a, and may correspond to a Z position of the front surface 100a of the object 100 to be charged. The exhaust air path EAS may extend obliquely in a direction intersecting the placement surface 2a in the vicinity of the exhaust port 33.

A structure including the intake air path IAS, the fan 5, and the exhaust air path EAS form the cooling system CST. In the cooling system CST, the fan 5 is driven to form an airflow as indicated by outlined arrows in FIG. 3. The air flows through the air intake port 21->the intake air path IAS (the internal space 22)->the air intake port 5a of the fan 5->the fan 5->the exhaust port 5b of the fan 5->the exhaust air path EAS (the internal space 32)->the exhaust port 33->the vicinity of the front surface 100a of the object 100 to be charged.

When passing through the intake air path IAS, the air exchanges heat with the heat source (e.g., the components or the like in the vicinity of the coil 6) in the charger 1, and cools the heat source in the charger 1 while the temperature of the air slightly rises. The temperature of the air is sufficiently lower than the temperature of the heat source (e.g., the components or the like in the vicinity of the coil 106) in the object 100 to be charged.

The air with a slightly raised temperature is increased in wind pressure by the fan 5, sent to the exhaust port 33 through the exhaust air path EAS, and blown out from the exhaust port 33. The air blown out from the exhaust port 33 is blown onto the front surface 100a of the object 100 to be charged. When the air passes near the front surface 100a of the object 100 to be charged, the air exchanges heat with the heat source in the object 100 to be charged, and cools the heat source in the object 100 to be charged while the temperature of the air more slightly rises. This air then flows in a direction away from the object 100 to be charged, and hardly affects the temperature of the object 100 to be charged.

In the cooling system CST, the fan 5 is the centrifugal fan, and easily increases the wind pressure as compared with an axial fan. Therefore, the fan 5 enables to increase the pressure of the air sucked from the intake air path IAS and blow out the air to the exhaust air path EAS. Therefore, the pressure of the air blown out from the exhaust port 33 can be sufficiently increased to effectively form the flow of air blown onto the front surface 100a of the object 100 to be charged, from the exhaust port 33.

This cooling system CST enables parallel cooling of the heat source in the charger 1 and the heat source in the object 100 to be charged, and thus the object 100 to be charged can be efficiently cooled. Therefore, the wireless charging can be efficiently performed, for example, the wireless charging can be continuously performed using a quick charging method.

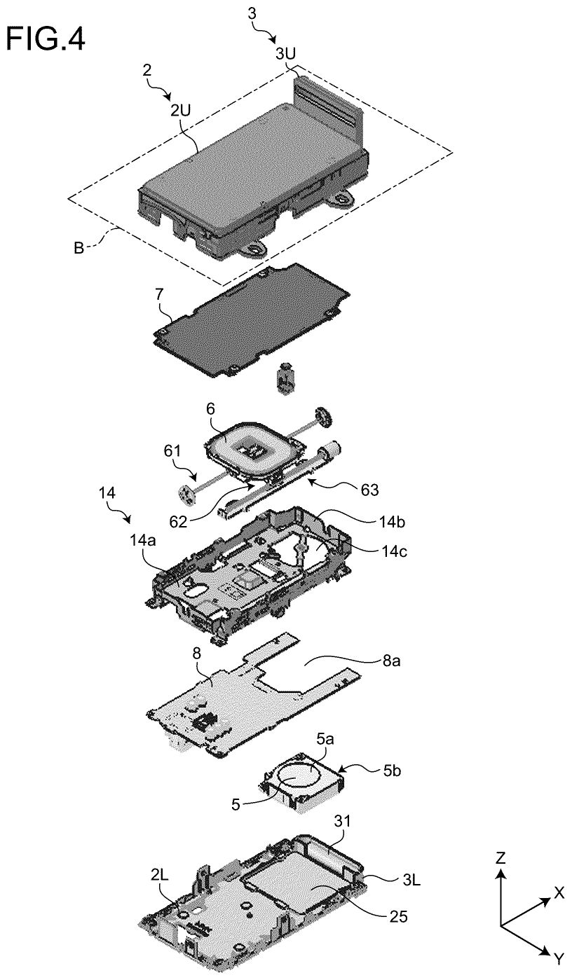

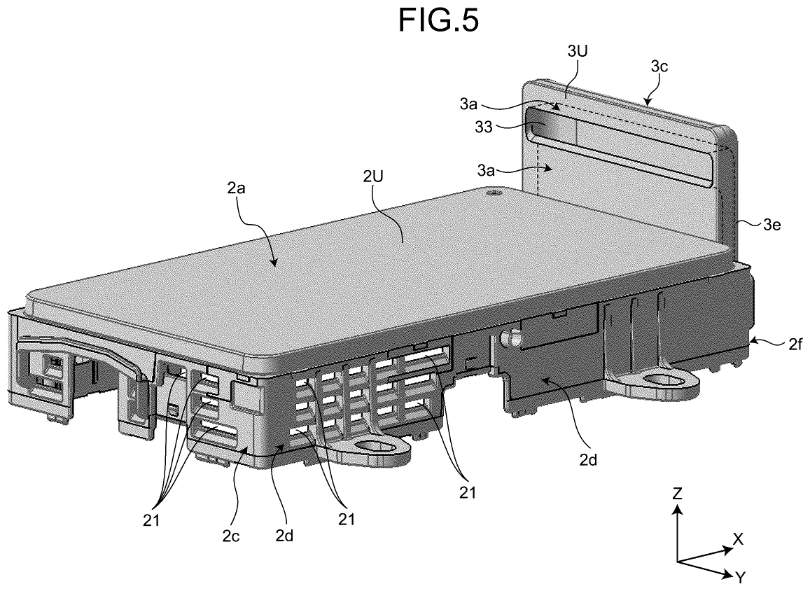

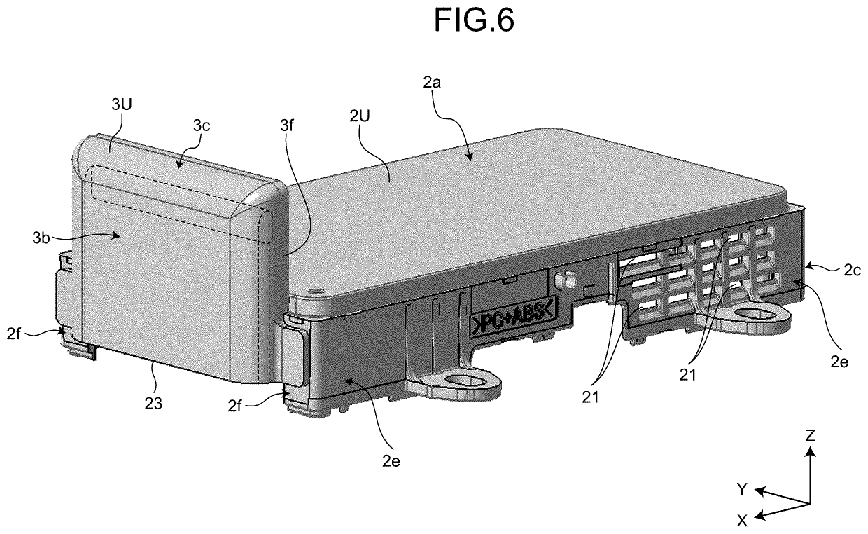

The structure of the charger 1 will be described in more detail with reference to FIGS. 1, 2, and 4 to 6. FIG. 4 is an exploded perspective view illustrating a configuration of the charger 1. FIG. 5 is a perspective view of a configuration of the housing 2 and the protrusion part 3, illustrating an enlarged perspective view of a part B in FIG. 4. FIG. 6 is a perspective view of a configuration of the housing 2, illustrating a perspective view of FIG. 5 as viewed from the opposite side (namely, +X side and −Y side).

In addition to the housing 2, the protrusion part 3, the fan 5, and the coil 6, the charger 1 includes a cover 12, a cover 13, a detection printed circuit board (PCB) 7, a main printed circuit board (PCB) 8, and a chassis 14.

The X direction of the housing 2 is defined as the longitudinal direction. The housing 2 may be a horizontal box-shaped member. The housing 2 includes the internal space 22. The housing 2 may have dimensions in the X direction and the Y direction that are larger than a dimension in the Z direction. The housing 2 includes an upper case 2U and a lower case 2L, the upper case 2U and the lower case 2L are fitted to each other in the Z direction, and formed as the box-shaped member. The upper case 2U can be formed of any electromagnetic wave transmissive material, and may be formed of a resin such as plastic. The lower case 2L can be formed of any material, and may be formed of a resin such as plastic.

The cover 12 mainly exposes the housing 2 on the +Z side and the −Z side, and covers the housing 2 from a −X side, a +Y side, the −Y side, and the +X side. The cover 12 can be formed of any material, and may be formed of a resin such as plastic.

The housing 2 includes the placement surface 2a, the bottom surface 2b, the end surface 2c, the end surface 2d, the end surface 2e, and an end surface 2f. The internal space 22 is a substantially rectangular parallelepiped space surrounded by the placement surface 2a, the bottom surface 2b, the end surface 2c, the end surface 2d, the end surface 2e, and the end surface 2f. The cover 12 exposes the placement surface 2a and the bottom surface 2b, and covers the end surface 2c, the end surface 2d, the end surface 2e, and the end surface 2f.

The placement surface 2a is disposed in the upper case 2U. The placement surface 2a extends in the X and Y directions and forms a surface of the housing 2 on the +Z side. The placement surface 2a may have a substantially rectangular shape with the X direction as a longitudinal direction. The placement surface 2a enables placement of the object 100 to be charged.

The object 100 to be charged may have a shape corresponding to the shape of the placement surface 2a, or may be a plate-shaped member. The object 100 to be charged includes the front surface 100a and the back surface 100b. The object 100 to be charged may be an electronic device such as a smartphone. The object 100 to be charged can be placed on the placement surface 2a with the orientation where the longitudinal direction is the X direction and the front surface 100a is directed to the +Z side. The object 100 to be charged is compatible with the wireless charging function of the charger 1, and includes the coil 106 and the battery 101. In the object 100 to be charged, the display structure (not illustrated) may be disposed in a region on a side of the front surface 100a, and the coil 106 may be disposed in a region on a side of the back surface 100b. The coil 106 is wound in a rotation direction around Z. The coil 106 is electrically connected to components disposed around the coil 106, and is further electrically connected to the battery 101. The coil 106 and the components around the coil 106 can be the heat source during wireless charging.

The bottom surface 2b is disposed in the lower case 2L. The bottom surface 2b extends in the X and Y directions and forms a surface of the housing 2 on the −Z side. The bottom surface 2b may have a substantially rectangular shape with the X direction as a longitudinal direction.

The end surface 2c is disposed in the upper case 2U and the lower case 2L. The end surface 2c extends in the Y and Z directions and forms a surface of the housing 2 on the −X side. The end surface 2c is provided with one or more air intake ports 21. Each of the air intake ports 21 extends in the X direction and penetrates a wall part of the end surface 2c and causes an external space of the housing 2 to communicate with the internal space 22. Each air intake port 21 may have a substantially rectangular shape in YZ plane view.

The end surface 2d is disposed in the upper case 2U and the lower case 2L. The end surface 2d extends in the X and Z directions and forms a surface of the housing 2 on the +Y side. The end surface 2d is provided with one or more air intake ports 21 in a region on the −X side. Each of the air intake ports 21 extends in the Y direction and penetrates a wall part of the end surface 2d and causes an external space of the housing 2 to communicate with the internal space 22. Each air intake port 21 may have a substantially rectangular shape in XZ plane view.

The end surface 2e is disposed in the upper case 2U and the lower case 2L. The end surface 2e extends in the X and Z directions and forms a surface of the housing 2 on the −Y side. The end surface 2e is provided with one or more air intake ports 21 in a region on the −X side. Each of the air intake ports 21 extends in the Y direction and penetrates a wall part of the end surface 2e and causes an external space of the housing 2 to communicate with the internal space 22. Each air intake port 21 may have a substantially rectangular shape in XZ plane view.

Note that one or more air intake ports 21 are preferably provided in the region of the housing 2 on the −X side, and may be provided in at least one of the end surface 2c, the end surface 2d, and the end surface 2e. Each of the air intake ports 21 may have a shape other than the substantially rectangular shape, in plane view.

The end surface 2f is disposed in the upper case 2U. The end surface 2f extends in the Y and Z directions and forms a surface of the housing 2 on the +X side. The end surface 2f is provided with an opening 23 (see FIGS. 2 and 6). The opening 23 extends in the X direction and penetrates a wall part of the end surface 2f and causes the exhaust port of the fan 5 to communicate with the exhaust port 33 via the internal space 32 (exhaust air path EAS). The opening 23 has a shape corresponding to a cross section of the flow path in the internal space 32, and may have a substantially rectangular shape with a rounded corner in the YZ plane view.

The protrusion part 3 is connected to the end of the housing 2 on the +X side. The protrusion part 3 has a Z-height that is larger than a Z-height of the housing 2. The protrusion part 3 may be substantially a vertical box-shaped member. The protrusion part 3 includes the internal space 32. The protrusion part 3 may have dimensions in the Y direction and the Z direction that are larger than a dimension in the X direction. The protrusion part 3 includes an upper case 3U and a lower case 3L, the upper case 3U and the lower case 3L are fitted to each other in the Z direction, and formed as the box-shaped member. The upper case 3U and the lower case 3L can be formed of any material, and may be formed of a resin such as plastic.

The cover 13 mainly exposes the protrusion part 3 on the −X side and the −Z side, and covers the protrusion part 3 from the +Y side, the −Y side, the +X side, and the +Z side. The cover 13 can be formed of any material, and may be formed of a resin such as plastic.

The protrusion part 3 includes the side surface 3a, a side surface 3b, an end surface 3c, an end surface 3d, an end surface 3e, and an end surface 3f. The internal space 32 is a substantially rectangular parallelepiped space surrounded by the side surface 3a, the side surface 3b, the end surface 3c, the end surface 3d, the end surface 3e, and the end surface 3f. The cover 13 exposes the side surface 3a and the end surface 3d, and covers the side surface 3b, the end surface 3c, the end surface 3e, and the end surface 3f.

The side surface 3a is disposed in the upper case 3U (see FIGS. 1, 2, and 5). The side surface 3a extends in the Y and Z directions and forms a surface of the protrusion part 3 on the −X side. The placement surface 2a may have a substantially rectangular shape with the Y direction as a longitudinal direction. The side surface 3a is provided with the exhaust port 33.

The exhaust port 33 may have a substantially rectangular shape with the Y direction as a longitudinal direction. A Y-direction width of the exhaust port 33 may correspond to a Y-direction width of the placement surface 2a. Therefore, when the object 100 to be charged, having a plate shape is disposed on the placement surface 2a, it is possible to form an airflow having a distribution shape (shape of a region having strong pressure) along the front surface 100a of the object 100 to be charged in a YZ cross-sectional view, and the object 100 to be charged can be effectively cooled.

The Z position of the exhaust port 33 is on the +Z side from the Z position of the placement surface 2a. A height H₃₃ of the exhaust port 33 from the bottom surface 2b is higher than a height H₂ₐ of the placement surface 2a from the bottom surface 2b.

The Z position of the exhaust port 33 may correspond to the Z position of the front surface 100a of the object 100 to be charged. The height H₃₃ of the exhaust port 33 from the bottom surface 2b may correspond to a height H₁₀₀ₐ of the front surface 100a of the object 100 to be charged from the bottom surface 2b. The height H₃₃ of the exhaust port 33 from the bottom surface 2b may be slightly higher than the height H₁₀₀ₐ of the front surface 100a of the object 100 to be charged from the bottom surface 2b.

Both inside surfaces 33a and 33b on both sides of the exhaust port 33 in the Z direction may be inclined in a direction intersecting the placement surface 2a. An extension plane of the inside surface 33a of the exhaust port 33 on the −Z side may intersect the placement surface 2a. An extension plane of the inside surface 33b of the exhaust port 33 on the +Z side may intersect the placement surface 2a.

The side surface 3b is provided on the upper case 3U (see FIG. 6). The side surface 3b extends in the Y and Z directions and forms a surface of the protrusion part 3 on the +X side. The side surface 3b may have a substantially rectangular shape with the Y direction as a longitudinal direction.

The end surface 3c is provided on the upper case 3U. The end surface 3c (see FIGS. 5 and 6) extends in the X and Y directions and forms a surface of the protrusion part 3 on the +Z side.

The end surface 3d is provided on the lower case 3L (see FIG. 2). The end surface 3d extends in the X and Y directions and forms a surface of the protrusion part 3 on the −Z side.

The end surface 3e is provided on the upper case 3U (see FIG. 5). The end surface 3e extends in the X and Z directions and forms a surface of the protrusion part 3 on the +Y side.

The end surface 3f is provided on the upper case 3U (see FIG. 6). The end surface 3f extends in the X and Z directions and forms a surface of the protrusion part 3 on the −Y side.

The protrusion part 3 has an opening 31 in a connection region to the housing 2 (see FIGS. 2 and 4). The opening 31 communicates with the opening 23 of the housing 2. The opening 31 communicates with the exhaust port 33 via the internal space 32. In other words, the exhaust port of the fan 5 communicates with the exhaust port 33 via the opening 23, the opening 31, and the internal space 32.

The detection PCB 7 is a substantially plate-shaped member, and can have a substantially rectangular shape corresponding to the placement surface 2a of the housing 2 in XY plane view (see FIG. 4). The detection PCB 7 is disposed on an inner surface of the upper case 2U on the −Z side. The detection PCB 7 may be bonded to the inner surface of the upper case 2U on the −Z side, via an adhesive or the like. The coil 6 is disposed on a surface of the detection PCB 7 on the −Z side, and predetermined components connected to the coil 6 are disposed around the coil 6. The coil 6 and the components around the coil 6 can be the heat source during wireless charging.

The coil 6 is disposed on the surface of the detection PCB 7 on the −Z side (see FIG. 2). The coil 6 is disposed on the surface of the detection PCB 7 on the −Z side, in a winding direction around a Z axis. The coil 6 may be disposed on the surface of the detection PCB 7 on the −Z side so as to be slidable in the X direction while maintaining the orientation thereof (see FIG. 4). The coil 6 is slidably held on a rail 61 in the X direction. The rail 61 extends in the X direction, and both ends thereof in the X direction are fixed to the surface of the detection PCB 7 on the −Z side. A movable member 62 is fixed to the coil 6. The movable member 62 is a motor or the like, and moves the coil 6 in the X direction along a movable rail 63 extending in the X direction, according to a control signal from a controller (not illustrated).

The fan 5 is the centrifugal fan and has a substantially rectangular parallelepiped shape (see FIG. 4). The fan 5 is provided with the air intake port 5a on the +Z side and the exhaust port 5b on the outside in the X and Y directions (+X side in FIG. 4).

A recess 25 corresponding to the fan 5 is provided in an inner surface of the lower case 2L on the +Z side. The recess 25 has a Z-height slightly smaller than that of the other region of the inner surface of the lower case 2L on the +Z side (see FIG. 2). The recess 25 has an XY planar shape that corresponds to an XY planar shape of the fan 5 and that may be slightly larger than the XY planar shape of the fan 5. The fan 5 is disposed in the recess 25 of the lower case 2L.

The main PCB 8 is a substantially plate-shaped member, and has a substantially U-shape in XY plane view (see FIG. 4). The main PCB 8 is disposed on the inner surface of the lower case 2L on the +Z side. The main PCB 8 may be bonded to the inner surface of the lower case 2L on the +Z side, via an adhesive or the like. The main PCB 8 has a cutout part 8a cut out toward the-X side, at an end on the +X side. The cutout part 8a has an XY planar shape that corresponds to the XY planar shape of the recess 25. The XY planar shape of the cutout part 8a corresponds to the XY planar shape of the fan 5, and may be slightly larger than the XY planar shape of the fan 5. The fan 5 is disposed in the cutout part 8a.

The chassis 14 is a substantially box-shaped member opened on the +Z side, and has an opening 14c near an end on the +X side. The chassis 14 covers the internal space 22 together with the detection PCB 7, from the outside. Furthermore, In the chassis 14, a part 14b on the +X side covers the protrusion part 3 from the −X side, and the other part 14a covers the main PCB 8 and the lower case 2L from the +Z side. An XY position of the opening 14c corresponds to an XY position of the fan 5. The opening 14c makes the internal space 22 communicate with the air intake port 5a of the fan 5.

As described above, according to the embodiment, in the charger 1, the air intake ports 21 are disposed in the end surface 2c of the housing 2, the exhaust port 33 is disposed in the side surface 3a of the protrusion part 3, and the fan 5 is disposed in the flow path extending from the air intake ports 21 to the exhaust port 33. When the fan 5 is driven, the region facing the internal space 22 in the charger 1 is cooled by air from each of the air intake ports 21 to the air intake port 5a of the fan 5 through the intake air path IAS. In addition, the region in the vicinity of the front surface 100a of the object 100 to be charged is cooled by air that is blown out from the exhaust port 33 through the exhaust air path EAS from the exhaust port 5b of the fan 5 and is then blown onto the front surface 100a of the object 100 to be charged. This configuration enables parallel cooling of the heat source in the charger 1 and the heat source in the object 100 to be charged, and the object 100 to be charged can be efficiently cooled. Therefore, the wireless charging can be efficiently performed, for example, the wireless charging can be continuously performed using a quick charging method.

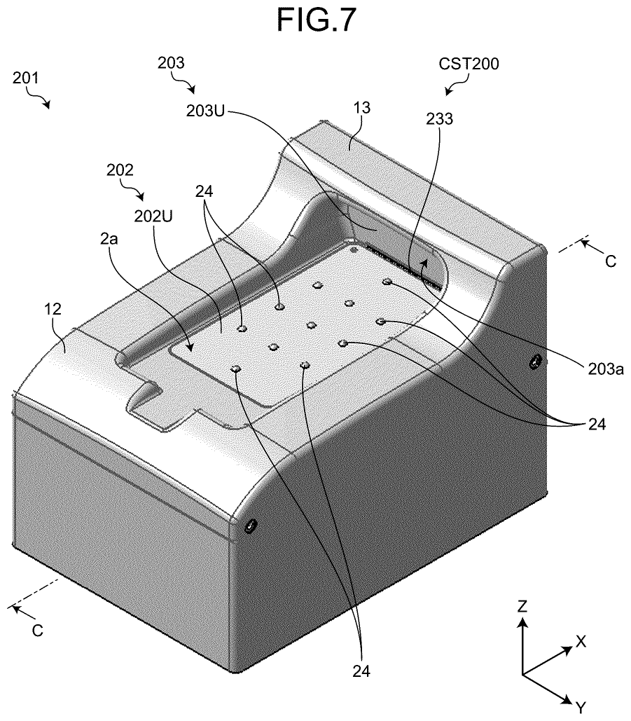

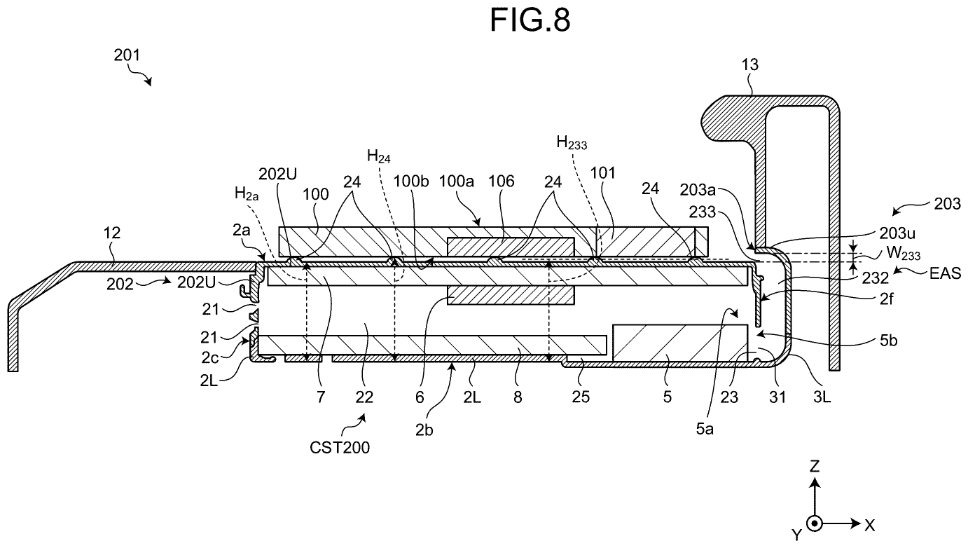

Note that, as illustrated in FIGS. 7 and 8 for a first modification of the embodiment, a charger 201 may be provided with a cooling system CST200 that enables parallel cooling of a region facing the internal space 22 in a charger 201 and a region in the vicinity of the back surface 100b of the object 100 to be charged. FIG. 7 is a perspective view illustrating an appearance configuration of the charger 201. FIG. 8 is a cross-sectional view of a configuration of the charger 201, illustrating a cross-section of FIG. 7 taken along line C-C.

The charger 201 includes a housing 202 and a protrusion part 203 instead of the housing 2 and the protrusion part 3 (see FIGS. 1 and 2). The housing 202 further includes a plurality of convex parts 24. The convex parts 24 are provided on the placement surface 2a. The convex parts 24 can be arranged in the X and Y directions on the placement surface 2a. The convex parts 24 have Z-heights equal to each other. This configuration makes it possible to form a gap having a Z-direction width equal in the X and Y directions, between the back surface 100b of the object 100 to be charged and the placement surface 2a, when the object 100 to be charged is placed on the placement surface 2a via the convex parts 24.

The protrusion part 203 includes an exhaust port 233 instead of the exhaust port 33 (see FIGS. 1 and 2). A height H₂₃₃ of the exhaust port 233 from the bottom surface 2b corresponds to the height H₂ₐ of the placement surface 2a from the bottom surface 2b. The height H₂₃₃ of the exhaust port 233 from the bottom surface 2b corresponds to a height H₂₄ of each of the convex parts 24 from the bottom surface 2b. A Z-direction width W₂₃₃ of the exhaust port 233 corresponds to a Z-height of the convex part 24 from the placement surface 2a.

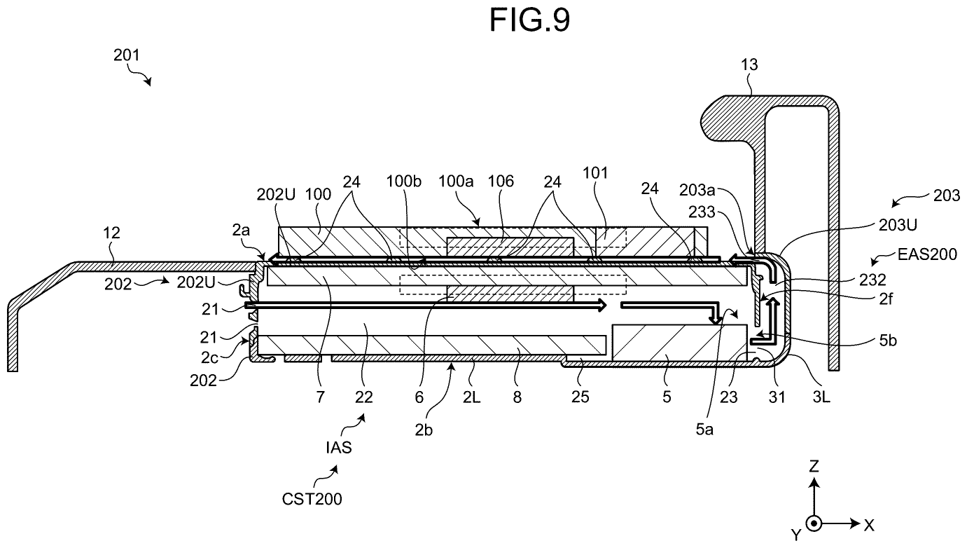

Arrangement of the fan 5 in the flow path extending from the air intake ports 21 to the exhaust port 233 is the same as described in the embodiment. As illustrated in FIG. 9, the internal space 22 of the housing 2 can be regarded as an intake air path IAS from the air intake port 21 to the air intake port 5a of the fan 5, and the internal space 232 of the protrusion part 203 can be regarded as an exhaust air path EAS200 from the exhaust port 5b of the fan 5 to the exhaust port 233.

A Z position of the exhaust port 233 corresponds to the Z position of the placement surface 2a, and may correspond to a Z position of each convex part 24. The exhaust air path EAS200 may extend in a direction along the placement surface 2a in the vicinity of the exhaust port 233.

A structure including the intake air path IAS, the fan 5, and the exhaust air path EAS200 forms the cooling system CST200. In the cooling system CST200, the fan 5 is driven to form an airflow indicated by outlined arrows in FIG. 9. The air flows through the air intake ports 21->the intake air path IAS (the internal space 22)->the air intake port 5a of the fan 5->the fan 5->the exhaust port 5b of the fan 5->the exhaust air path EAS200 (the internal space 232)->the exhaust port 233->the gap between the placement surface 2a and the back surface 100b of the object 100 to be charged.

When passing through the intake air path IAS, the air exchanges heat with the heat source (e.g., the components or the like in the vicinity of the coil 6) in the charger 201, and cools the heat source in the charger 201 while the temperature of the air slightly rises. The temperature of the air is sufficiently lower than the temperature of the heat source (e.g., the components or the like in the vicinity of the coil 106) in the object 100 to be charged.

The air having a slightly raised temperature is increased in wind pressure by the fan 5, sent to the exhaust port 233 through the exhaust air path EAS200, and blown out from the exhaust port 233. The air blown out from the exhaust port 233 is blown onto one end (an end on the +X side in FIG. 9) of the gap between the placement surface 2a and the back surface 100b of the object 100 to be charged. When the air passes through the gap between the placement surface 2a and the back surface 100b of the object 100 to be charged, the air exchanges heat with the heat source in the object 100 to be charged, and cools the heat source in the object 100 to be charged while the temperature of the air more slightly rises. This air then flows in a direction away from the object 100 to be charged, and hardly affects the temperature of the object 100 to be charged.

This cooling system CST200 also enables parallel cooling of the heat source in the charger 201 and the heat source in the object 100 to be charged, and the object 100 to be charged can be efficiently cooled. Therefore, the wireless charging can be efficiently performed, for example, the wireless charging can be continuously performed using a quick charging method.

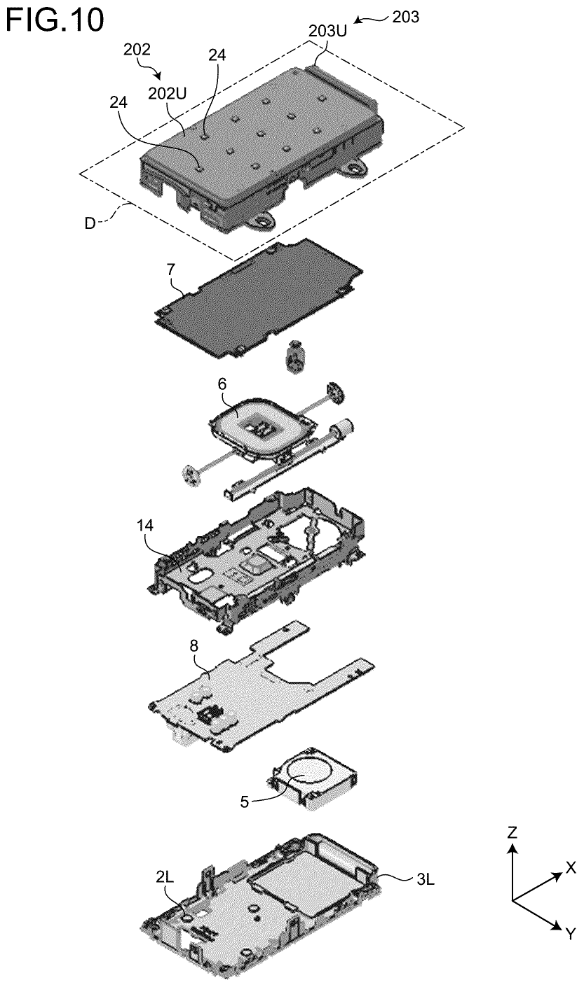

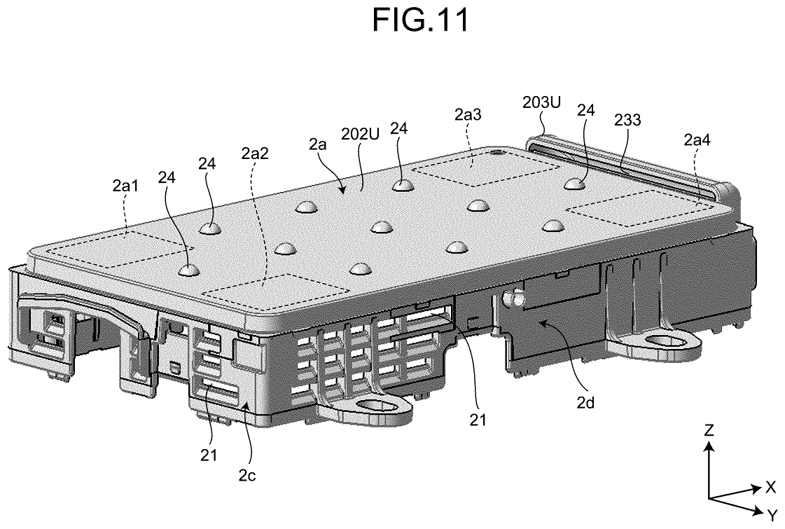

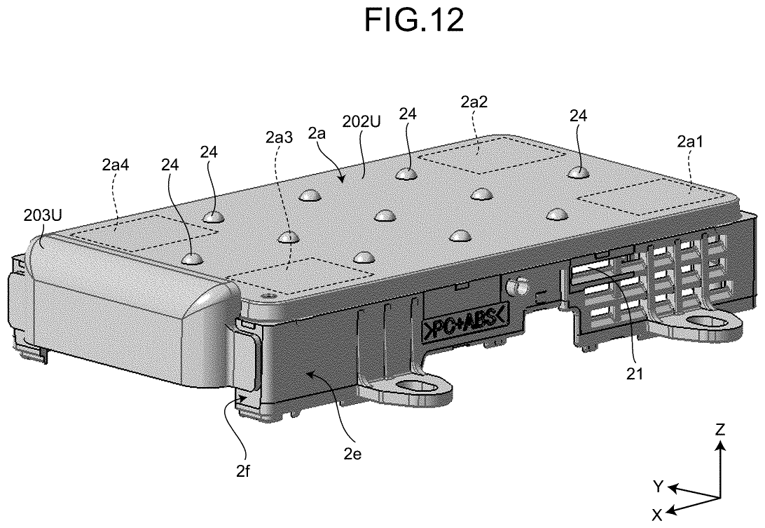

A structure of the charger 201 will be described in more detail with reference to FIGS. 7, 8, and 10 to 12. FIG. 10 is an exploded perspective view illustrating the configuration of the charger 201. FIG. 11 is a perspective view of a configuration of the housing 202, illustrating an enlarged perspective view of a part D in FIG. 10. FIG. 12 is a perspective view of a configuration of the housing 202, illustrating a perspective view of FIG. 11 as viewed from the opposite side (namely, +X side and −Y side).

The object 100 to be charged is placed on the placement surface 2a of the housing 202 via the plurality of convex parts 24. In a case where the object 100 to be charged is an electronic device such as a smartphone, a step part (e.g., a camera module part) partly protruding into a step shape may be provided on the back surface 100b of the object to be charged.

Meanwhile, the convex parts 24 may be provided on the placement surface 2a so as to avoid regions 2a1 to 2a4 in the placement surface 2a, which correspond to the step part on the back surface 100b. In a case where the placement surface 2a has a substantially rectangular shape, the regions 2a1 to 2a4 corresponding to the step part may be regions near the corner parts. In this case, the convex parts 24 may have Z-heights equal to each other, each corresponding to the height of the step part. This configuration makes it possible to form the gap having a Z-direction width equal in the X and Y directions, between the back surface 100b of the object 100 to be charged and the placement surface 2a, when the object 100 to be charged is placed on the placement surface 2a via the convex parts 24.

The Z position of the exhaust port 233 (see FIG. 8) is lower than the Z position of the exhaust port 33 (see FIG. 2). Accordingly, a Z-height of the protrusion part 203 (see FIGS. 10 to 12) may be lower than the Z-height of the protrusion part 3 (see FIGS. 4 to 6). As a result, as illustrated in FIG. 10, the structure of the charger 201 can be readily downsized.

The charger 201 configured as described above also enables parallel cooling of the heat source in the charger 201 and the heat source in the object 100 to be charged, and thus the object 100 to be charged can be efficiently cooled. As a result, the wireless charging can be efficiently performed such as that the wireless charging can be continuously performed using a quick charging method.

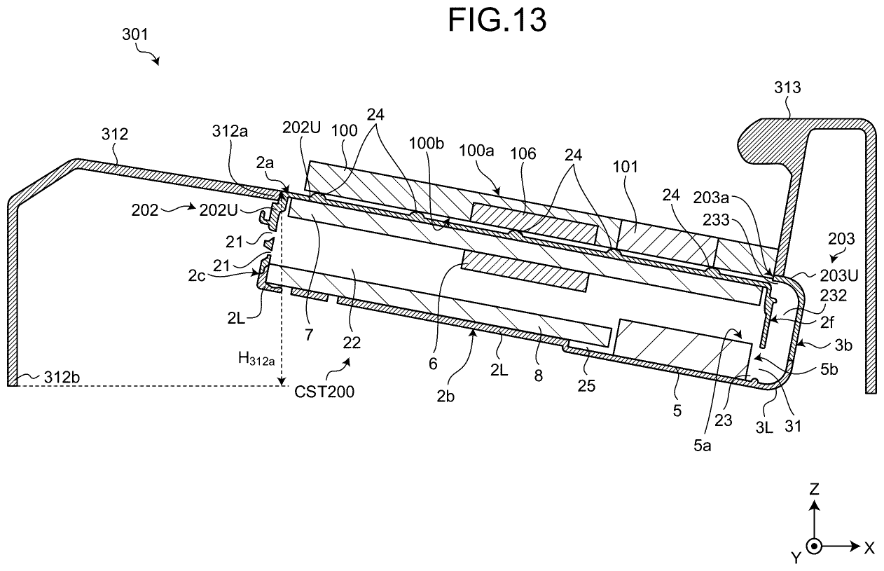

Furthermore, as illustrated in FIG. 13 for a second modification of the embodiment, the placement surface 2a may be configured to be inclined against a horizontal plane in a position in use (e.g., a position when placed on a substantially horizontal surface) of a charger 301. FIG. 13 is a cross-sectional view illustrating a configuration of the charger 301, and corresponds to the cross-section taken along line C-C of FIG. 7.

The charger 301 includes covers 312 and 313 in place of the covers 12 and 13 (see FIG. 8). The cover 312 holds the housing 202 such that an end of the housing 202 on the −X side is positioned on the +Z side from an end on the +X side. A Z-height of the cover 312 is, for example, higher than a Z-height of the housing 202. An end 312a of the cover 312 on the +X side is connected to the vicinity of an end of the end surface 2c of the housing 202 on the +Z side. A height H₃₁₂ₐ of the end 312a of the cover 312 on the +X side from an end 312b on the −Z side is larger than the height H₂ₐ of the placement surface 2a of the housing 202 from the bottom surface 2b (see FIG. 8). Therefore, the placement surface 2a is inclined such that the Z-height increases with distance from the protrusion part 203.

Accordingly, the cover 313 is inclined such that a side surface on the −X side is closer to the −X side as the side surface on the −X side is closer to the placement surface 2a. An extension plane of the side surface of the cover 313 on the −X side may be substantially orthogonal to the placement surface 2a.

In this configuration, the placement surface 2a is inclined against the horizontal plane, when the object 100 to be charged is placed on the placement surface 2a via the plurality of convex parts 24, in a position in use (e.g., a position when placed on a substantially horizontal surface) of the charger 301. In FIG. 13, the XY plane represents a horizontal plane. The action of gravity makes it easy to move the object 100 to be charged to the +X side, and an end surface of the object 100 to be charged on the +X side can abut on the side surface of the cover 313 on the −X side.

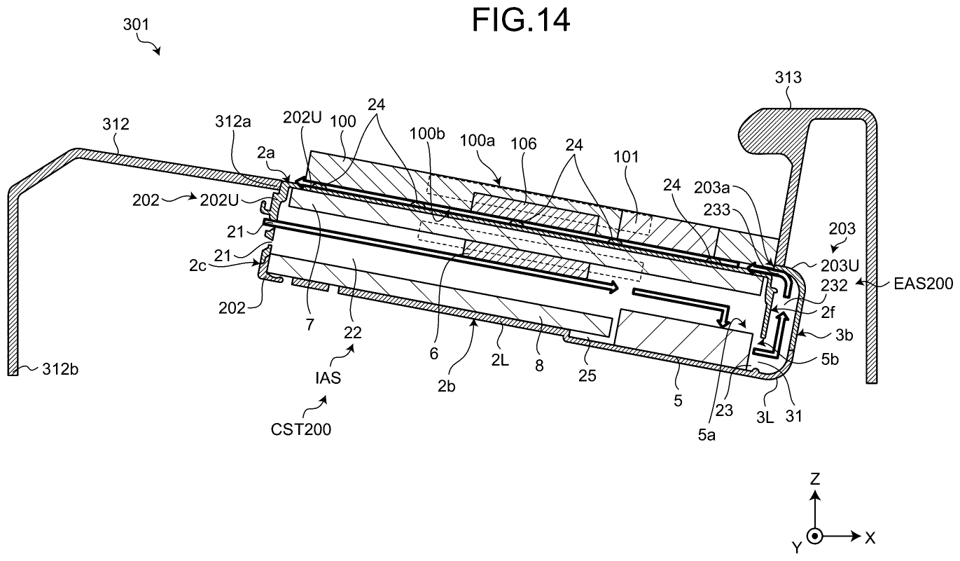

Therefore, by driving the fan 5 in the cooling system CST200, the air blown out from the exhaust port 233 can be efficiently guided to the gap between the placement surface 2a and the back surface 100b of the object 100 to be charged, as indicated by outlined arrows in FIG. 14. As a result, the flow rate of air passing through the gap between the placement surface 2a and the back surface 100b of the object 100 to be charged can be further increased, the efficiency in heat exchange with the heat source in the object 100 to be charged can be improved, and efficiency of cooling the heat source in the object 100 to be charged can be improved.

According to the structure of the cooling system CST200 and the covers 312 and 313, as described above, the efficiency of cooling the object 100 to be charged can be further improved.

The charger according to the present disclosure enables efficient cooling.

While certain embodiments have been described, these embodiments have been presented by way of example only, and are not intended to limit the scope of the inventions. These embodiments described herein may be embodied in a variety of other forms, furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A charger comprising:
a housing whose longitudinal direction is a first direction, the housing including a placement surface enabling placement of an object to be charged, a bottom surface on an opposite side of the placement surface, and an end surface provided with an air intake port;
a protrusion part connected to one end of the housing in the first direction, the protrusion part protruding from the one end in a second direction intersecting the first direction, the protrusion part including a side surface facing the placement surface, the side surface being provided with an exhaust port; and
a fan disposed in a flow path extending from the air intake port to the exhaust port.

2. The charger according to claim 1, wherein a height of the exhaust port from the bottom surface is larger than a height of the placement surface from the bottom surface.

3. The charger according to claim 2, wherein the height of the exhaust port from the bottom surface corresponds to a height of a front surface of the object to be charged from the bottom surface.

4. The charger according to claim 1, wherein inside surfaces on both sides of the exhaust port in the second direction are inclined in a direction intersecting the placement surface.

5. The charger according to claim 1, wherein a longitudinal direction of the exhaust port is a third direction intersecting the first direction and the second direction.

6. The charger according to claim 5, wherein a width of the exhaust port in the third direction corresponds to a width of the placement surface in the third direction.

7. The charger according to claim 1, wherein the flow path includes an intake air path communicating between an exhaust port of the fan and the exhaust port, the intake air path being part of the flow path, the intake air path obliquely extending near the exhaust port in a direction intersecting the placement surface.

8. The charger according to claim 7, wherein the flow path further includes an exhaust air path communicating between the air intake port and an air intake port of the fan, the exhaust air path being another part of the flow path.

9. The charger according to claim 1, wherein
the fan is disposed on one end side of the housing in the first direction, and
the air intake port is disposed on the other end side of the housing in the first direction.

10. The charger according to claim 1, wherein
the housing has a first opening at the one end,
the protrusion part has a second opening communicating with the first opening in a connection region to the housing, and
an exhaust port of the fan communicates with the exhaust port via the first opening and the second opening.

11. The charger according to claim 1, wherein the fan is disposed near the bottom surface in the housing, the fan has an air intake port on an opposite side of the bottom surface, and the fan has an exhaust port at a side end near the protrusion part.

12. The charger according to claim 1, wherein the fan is a centrifugal fan.

13. The charger according to claim 1, wherein a height of the exhaust port from the bottom surface corresponds to a height of the placement surface from the bottom surface.

14. The charger according to claim 1, wherein the housing further includes a plurality of convex parts provided on the placement surface.

15. The charger according to claim 14, wherein a height of the exhaust port from the bottom surface corresponds to a height of the convex part from the bottom surface.

16. The charger according to claim 14, wherein a width of the exhaust port in the second direction corresponds to a height of the convex part from the placement surface.

17. The charger according to claim 1, wherein the placement surface is inclined such that a height in the second direction increases with distance from the protrusion part.

18. The charger according to claim 1, wherein
the placement surface enables placement of the object to be charged having a first coil, and
the charger further includes a second coil disposed at a position corresponding to the first coil and disposed near the placement surface in the housing.
